(19) United States
(12) Patent Application Publication
(10) Pub. No.: US 2002/0192601 A1
(43) Pub. Date: Dec. 19, 2002

(54) Process for the production of film having refractive index distribution

(75) Inventor: Masaaki Takasuka, Tokyo (JP)

Correspondence Address: SUGHRUE MION, PLLC, 2100 Pennsylvania Avenue, NW, Washington, DC, 20037-3213, US

(73) Assignee: MITSUBISHI GAS CHEMICAL COMPANY, INC.

(21) Appl. No.: 10/127,500

(22) Filed: Apr. 23, 2002

(30) Foreign Application Priority Data
Apr. 24, 2001 (JP) 125572/01

(51) Int. Cl. G03F 1/00; G03C 1/73

(52) U.S. Cl. 430/321; 430/280.1

(57) ABSTRACT

A process for the production of a film having a refractive index distribution, comprising producing a film by using an organic solvent solution containing as essential components a thermoplastic resin, a photopolymerizable monomer and a photopolymerization initiator, exposing the film to light and developing the film,

wherein a highly viscous solution containing as essential components a thermoplastic resin, a photopolymerizable monomer and a photopolymerization initiator and containing substantially no organic solvent is used in place of the organic solvent solution used for the production of the film.

### FIELD OF THE INVENTION

The present invention relates to a process for the production of a film having a refractive index distribution such as an optical waveguide or a hologram used for an optical integrated circuit and an optical communication.

### BACKGROUND OF THE INVENTION

Optical waveguides or holograms have been used for an optical communication or an information recording.

Optical waveguides are an optical transmission path in which light propagates in an area surrounded with a medium having a low refractive index by repeating a total reflection at its boundary surface.

The above “total reflection” is different from a usual optical reflection. The total reflection is a phenomenon in which, when the incident angle of light entering from a transparent medium having a high refractive index to a medium having a low refractive index is smaller than a certain angle, all the energy of the light is reflected at its boundary surface without any loss. The above phenomenon is utilized for an optical fiber and the like.

Optical waveguides are an optical element which freely has a branch structure or an integrated structure by means of an ultraviolet lithography or an electron beam lithography and therefore they are different from optical fibers. They are used as an information communication material.

Further, holograms are an interference fringe produced by exposing a photosensitive material to two light beams having high coherence. They are used as an information recording material, a reflecting plate, an optical filter or a grating waveguide by using the diffraction phenomenon of the interference fringe.

A material for producing the above optical waveguide and hologram includes an organic polymer, quartz, a heavy metal oxide and a liquid crystal. Among the above materials, when an optical waveguide or a hologram is produced from an organic polymer as a raw material, there can be adopted a method in which a pattern is formed by means of a photochemical reaction. Therefore, in comparison with other materials, the use of organic polymer has the advantages that it is economical and that the production process is simple.

As a conventional production process for a polymer optical waveguide, first, Concrete Example 1 of JP-A-50-022648 discloses a method (casting method) in which a film is formed from a solution containing polymethyl methacrylate, a photopolymerizable monomer and a photopolymerization initiator and the film is exposed to light through a mask.

Concrete Example 2 of JP-A-50-022648 discloses a method (monomer diffusion method) in which a polycarbonate film is impregnated with a methanol solution containing a photopolymerizable monomer and a photopolymerization initiator to prepare a film in which the photopolymerizable monomer and the photopolymerization initiator are diffused, and the film is exposed to light through a mask. Further, JP-A-52-138146 discloses a case where a polycarbonate Z (a polycarbonate resin from 1,1-bis(4-hydroxyphenyl) cyclohexane) is used in the above monomer diffusion method.

For example, “Optical integrated circuit—foundation and application” (compiled by The Japan Society of Applied Physics, KOGAKU-KONWAKI; published by ASAKURA SHOTEN (1988)) describes the principle of a process for the production of a polymer waveguide or a hologram. According to this book, first, a thermoplastic resin film containing a photopolymerizable monomer is formed on a substrate such as a glass plate by a dipping method, a spin coating method, a casting method, a laminate method or other methods. Then, the thermoplastic resin film containing a photopolymerizable monomer is exposed to light to react the photopolymerizable monomer site-selectively. Then, an unpolymerized photopolymerizable monomer is removed, to produce a film having a refractive index distribution in the film itself. According to this method, there can be produced a film having a thickness of 20 to 200 μm and a refractive index difference n_{D} of up to approximately 0.1. The refractive index difference n_{D} is a difference between a portion having a high refractive index and a portion having a low refractive index.

Among the production processes of a polymer waveguide, the casting method of the above-mentioned Concrete Example 1 has the following problems. The problems are that it takes a long time to produce a film by casting, that the concentration distribution of the photopolymerizable monomer in the film is liable to be large, and that variations between lots are liable to be large. For these reasons, the production of a homogeneous large-area film is impossible and there is no scalability. Further, the monomer diffusion method of the above-mentioned Concrete Example 2 also has the following problems. The problems are that it takes a long time to diffuse the photopolymerizable monomer and the photopolymerization initiator, that the film swells and deforms at the above diffusion operation time so that a positional accuracy deteriorates when handling the film alone, and that there is no reproducibility between lots.

The present inventors have made diligent studies about the above problems of the casting method of the Concrete Example 1, that is, the shortening of a production time, the evenness of concentration distribution of the photopolymerizable monomer in the film and the reproducibility between lots. According to documents concerning the above method of the Concrete Example 1, the use of an organic solvent is indispensable. There are no prior arts which do not use an organic solvent.

The evenness of concentration distribution of the photopolymerizable monomer in the film and the reproducibility between lots directly concern the performance of a produced optical waveguide. A factor, which impairs the evenness of concentration distribution in the film and the reproducibility between lots, is as follows. Generally, the photopolymerizable monomer to be used is volatile and organic solvent has a remarkably high volatility so that the remaining amounts of the organic solvent and the photopolymerizable monomer in the film vary depending upon a slight difference of a condition before preparing a film exposable to light.

For controlling it, a predetermined amount of a solution for casting was treated in a temperature-controlled closed system, and the relationship between the concentration of the organic solvent (solvent steam pressure partial pressure) in the atmosphere of the above closed system and the concentration of the organic solvent in the film was quantitatively grasped.

During the above experiment, a colorless transparent gel substance formed of a photopolymerizable monomer and a thermoplastic resin and containing substantially no solvent was confirmed. And it has been confirmed that a film can be produced by using the above colorless transparent gel substance.

The present inventors have found that the above problems are overcome by using the above colorless transparent gel substance, that is, a highly viscous resin solution containing a photopolymerizable monomer and a thermoplastic resin and containing substantially no organic solvent.

### SUMMARY OF THE INVENTION

It is an object of the present invention to provide a process for the production of a film having a refractive index distribution which film has a homogenous photopolymerizable monomer concentration distribution in a film and has excellent reproducibility between lots.

It is another object of the present invention to provide a process for the production of a film having a refractive index distribution, of which the production time is shortened.

According to the present invention, there is provided a process for the production of a film having a refractive index distribution, comprising producing a film by using an organic solvent solution containing as essential components a thermoplastic resin, a photopolvmerizable monomer and a photopolymerization initiator, exposing the film to light and developing the film, wherein a highly viscous solution containing as essential components a thermoplastic resin, a photopolymerizable monomer and a photopolymerization initiator and containing substantially no organic solvent is used in place of the organic solvent solution used for the production of the film.

In the present invention, preferably, the objective substance (film having a refractive index distribution) is obtained by exposure to light through a mask for an optical waveguide.

In the present invention, preferably, the thermoplastic resin is a homo- or co-polycarbonate resin having, as an essential constitutional unit, a constitutional unit induced from 1,1-bis(4-hydroxyphenyl)cyclohexane or a constitutional unit induced from a compound having from 5 to 100, particularly preferably from 21 to 37, dimethylsilyl ether units on average and having hydroxyphenyl groups at both the terminals of the dimethylsilyl ether units.

In the present invention, preferably, the photopolymerizable monomer is an ester of an acrylic acid or a methacrylic acid.

### BRIEF DESCRIPTION OF DRAWINGS

FIG. 1 is a schematic diagram of a Y-branch optical waveguide.

FIG. 2 shows the wavelength dependencies of refractive indexes concerning parts of the used polycarbonate resins.

FIG. 3 shows the wavelength dependencies of core and clad refractive indexes of one optical waveguide example using a produced polycarbonate Z.

FIG. 4 shows the wavelength dependencies of core and clad refractive indexes of parts of the produced optical waveguides.

### DETAILED DESCRIPTION OF THE INVENTION

The constitution of the present invention will be explained hereinafter.

As a thermoplastic resin used for the colorless transparent highly-viscous solution of the present invention, there can be used a thermoplastic resin which has a low crystallinity and a high solubility in a photocurable resin monomer and has an appropriate refractive index difference from a polymer of a photocurable resin monomer to be used.

As a transparent thermoplastic resin, polycarbonate, polysulphone, polyphenylene ether, polystyrene, a styrene-ethyl acrylate copolymer resin and the like can be used. Within a transparent and homogenous range, these resins may be used in combination as required. For example, at least two thermoplastic resins having different refractive indexes are combined and the resultant mixture can be used as a resin mixture having an intermediate refractive index.

Of these, particularly, there can be preferably used a homopolycarbonate or copolycarbonate resin having, as an essential constitutional unit, a constitutional unit induced from 1,1-bis(4-hydroxyphenyl)cyclohexane or a constitutional unit induced from a compound having hydroxyphenyl groups at both the terminals of dimethylsilyl ether units (21 to 37 dimethylsilyl ether units on average), since the above homopolycarbonate or copolycarbonate resin has an absorption band in a near infrared region and a near ultraviolet region but shows a stable refractive index in a broad wavelength range.

The photopolymerizable monomer is selected from aliphatic compounds having a carbon-carbon unsaturated double bond. In particular, an acrylic compound and a methacrylate compound are preferred.

Concretely, the acrylic compound includes methylacrylate, ethylacrylate, 2-methoxyethylacrylate, 2-phenoxyethylacrylate, 1,4-butanediol diacrylate, vinyl acrylate, allyl acrylate, benzil acrylate, isobornyl acrylate, dimethylaminoethyl acrylate, isobutyl acrylate, 3-methoxybutylacrylate, lauryl acrylate, ethyl-3-dimethylaminoacrylate, ditrimethylolpropane tetraacrylate, dipentaerythritol hexaacrylate, dipentaerythritol pentaacrylate, n-stearyl acrylate, tetraethyleneglycol diacrylate, tetrahydrofurfuryl acrylate, tripropyleneglycol diacrylate, trimethylolpropane triacrylate, neopentyl glycol diacrylate, neopentyl glycol hydroxypivalic acid ester diacrylate, 1,9-nonanediol diacrylate, 2-propenoic acid[2-[1,1-dimethyl-2-[(1-oxo-2-propenyl)oxy]ethyl]-5-ethyl-1,3-dioxane-5-yl]methyl ester, 1,6-hexanediol diacrylate and pentaerythritol triacrylate.

The methacrylate compound includes methyl methacrylate, ethyl methacrylate, n-butyl methacrylate, i(iso)-butyl methacrylate, t(tert)-butyl methacrylate, 2-ethylhexyl methacrylate, 2-methoxyethyl methacrylate, 2-phenoxyethyl methacrylate, 1,4-butanedioldimethacrylate, vinyl methacrylate, allyl methacrylate, benzil methacrylate, lauryl methacrylate, tridecyl methacrylate, stearyl methacrylate, cyclohexyl methacrylate, dimethylaminoethyl methacrylate, diethylaminoethyl methacrylate, glycidyl methacrylate, tetrahydrofurfuryl methacrylate, ethylene glycol dimethacrylate, triethylene glycol dimethacrylate, tetraethylene glycol dimethacrylate, 1,3-butylene glycol dimethacrylate and trimethylolpropane trimethacrylate.

Further, in order to initiate and promote a photopolymerization, a photopolymerization initiator or a photosensitizer in a small amount is used in combination as required. The photopolymerization initiator includes acetophenones such as acetophenone, 2-hydroxy-2-methyl-1-phenylpropane-1-one, dichloroacetophenone, trichloroacetophenone, p-t-butyldichloroacetophenone, biacetyl and 2,2-diethoxyacetophenone, benzophenone, Michler's ketone, benzil, benzoin, benzoin isobutyl ether, benzil dimethyl ketal, tetramethyl thiuram sulfide, thioxanthone, azobisisobutyronitrile, benzoyl peroxide, 1-hydroxycyclohexyl phenyl ketone, α-hydroxyisobutylphenon, p-isopropyl-α-hydroxyisobutylphenon, p-isopropyl-α-hydroxyisobutylphenon, 2,2-dimethoxy-2-phenylacetophenone, 1-hydroxycyclohexyl phenyl ketone, benzoin isopropyl ether, p-t-butyldichloroacetophenone, 1-phenyl-1,2-propanedione-2-(O-ethoxycarbonyl)oxime, 2-chlorothioxanthone, 2-methylthioxanthone, dibenzosuberone, α,α-dichloro-4-phenoxyacetophenone and 2-ethylanthraquinone.

Examples of the photosensitizer containing a sensitizing dye include n-butylamine, di-n-butylamine, triethylamine, diethylaminoethyl methacrylate, piperidine, O-tolylthio urea, sodium diethyldithiophosphate, tri-n-butylphosphine, sodium diethylthiophosphate, Michler's ketone, carbon tetrachloride and hexachloroethane.

For increasing the site selectivity of a radical reaction and storage stability, further, the gel mixture solution can contain a radical reaction inhibitor. Examples of the radical reaction inhibitor include hydroquinone, quaternary ammonium chloride, diethylhydroxyamine, cyclic amide, a nitryl compound, substitution urea, benzothiazole, hydroquinone monomethyl ether; organic acids such as lactic acid, oxalic acid and benzoic acid; and copper naphthenate.

Generally, a thermoplastic resin having a high transparency is dissolved in an excessive amount of the photopolymerizable monomer, whereby a colorless transparent highly-viscous solution (gel solution) is produced.

The method for dissolving the thermoplastic resin in the photopolymerizable monomer is as follows. Generally, a powder of the thermoplastic resin is mixed with the photopolymerizable monomer and the mixture is allowed to stand with stirring at intervals until the thermoplastic resin powder is completely dissolved in the photopolymerizable monomer. When the photopolymerizable monomer has a high stability, a stirring, an ultrasonic vibration, a heating up to a temperature lower than a thermal polymerization initiation temperature or other treatments may be used as required.

Generally, the colorless transparent high viscosity solution obtained above is applied to a glass substrate or the like by a doctor blade method or other methods to form a coating film. And, the photopolymerizable monomer amount in the coating film is controlled (generally allowed to stand in a predetermined atmosphere for a predetermined period of time), to obtain a film having a predetermined photopolymerizable monomer content.

The photopolymerizable monomer is volatilized from the coating film produced by a doctor blade method or the like by the standing after the production so that the amount of the phoropolymerizable monomer in the coating film decreases. Therefore, the component ratio of the coating film is changed. For this reason, for obtaining a film having an intended component ratio and a predetermined thickness, it is required to form a coating film in advance and grasp the change of component ratio of the coating film according to a standing time.

A produced waveguide has the best component ratio according to its components.

Generally, when components used and an atmosphere used are specified in the production of a film from the colorless transparent highly-viscous solution used in the present invention, the concentration distribution of the photopolymerizable monomer in the film can be controlled in the range of 10 wt % or lower, preferably 5 wt % or lower, based on the remaining monomer. Further, between produced films, the concentration distribution can be controlled in the range of 15 wt % or lower, preferably 10 wt % or lower, based on the remaining monomer. Therefore, a high yield production process can be actualized.

Generally, a mask made of a quartz glass or the like is placed on the above film and the film is exposed to ultraviolet light through the mask, whereby the photopolymerizable monomer is site-selectively reacted to form a polymer (exposure). The above exposure is carried out such that the irregular reflection of ultraviolet light is inhibited.

The mask on the polymer film obtained by reacting the photopolymerizable monomer site-selectively by the exposure was removed. Generally, the film is placed on a substrate and the film with the substrate is immersed in a poor solvent of a thermoplastic resin to remove an unreacted photopolymerizable monomer. Then, the film is dried to remove the poor solvent.

In a conventional step using an organic solvent, a film under manufacturing is separated during the step of removing an unreacted photopolymerizable monomer by the immersion in the poor solvent or during the step of drying. However, in the present invention, while the film is generally easily separated from the substrate, the film is not naturally separated from the substrate. Generally, the film is separated from the substrate after the step of removing an unreacted photopolymerizable monomer by the immersion in the poor solvent and then the separated film is dried.

The above-produced film having a refractive index, provided by the present invention, is generally held on a holding substrate or the like and then used. When an optical waveguide is produced, for example, respective optical waveguide parts are produced by a method in which a film having a plurality of refractive indexes for optical waveguide parts is produced, then the film, as it is, is held on the holding substrate and integrated with the holding substrate and then the film is cut to obtain respective optical waveguide parts as a product.

As the above holding substrate, a glass is the most general. A plastic film also can be used.

### EXAMPLES

The present invention will be explained more concretely with reference to Examples hereinafter.

### Example 1

### (1). Preparation of a Solventless Resin/Photopolymerizable Monomer Solution

60 g of methylmethacrylate, 30 g of a polycarbonate resin (“PCZ” hereinafter) having a viscosity-average molecular weight (M) of 20,000 from 1,1-bis(4-hydroxyphenyl) cyclohexane, and 0.3 g of 2-hydroxy-2-methyl-1-phenylpropane-1-one as a photopolymerization initiator were added to a reagent bottle having a volume of 500 ml. The reagent bottle was sealed. The reagent bottle was allowed to stand for three days at room temperature while agitating the mixture at intervals, whereby a colorless transparent highly-viscous solution was prepared. This mixture solution had a viscosity of 9.56 Pa·s, measured with a circular cone-circular plate viscosimeter.

### (2). Production of a Film

A film was obtained by using the above-prepared highly-viscous solution having no solvent with a coating composition-forming device having sealing and air-current-adjustment functions.

The above-prepared highly-viscous solution was applied on a surface of a soda glass (125 mm×125 mm, thickness 1.13 mm) having 30° C. by a doctor blade method under atmospheric pressure at a rate of 1 cm/second to form a coating film having a thickness of 170 μm. After the formation of the coating film, the film was allowed to stand for 8 minutes.

As a result, the methylmethacrylate was evaporated from the film surface to obtain a film having a thickness of approximately 40 μm and having a methyl methacrylate content of approximately 23 wt % based on the weight of the film.

### (3). Exposure

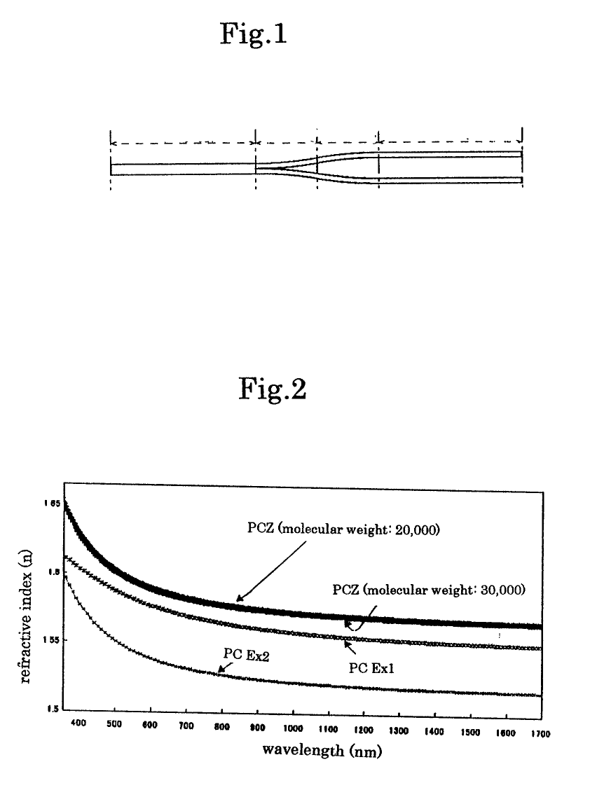

A mask made of a quartz glass for producing a plurality of Y-branch optical waveguides (before a branch: width 42.9 μm, after a branch: width 22.1 μm), illustrated in FIG. 1, at the same time was disposed on the above-produced film.

Pure water for inhibiting the irregular reflection of ultraviolet light used for exposure and for keeping warmth was poured into a water bath such that the depth of the pure water was approximately 1 cm. The soda glass and film, on which the mask made of a quartz glass was placed, was moved into a glass cell case having a size of 15 cm×15 cm and a depth of 3 cm for floating it on the pure water in the water bath.

Then, the glass cell case in the water bath having 30° C. was kept under a nitrogen current of 14 mL/minute for 1 minute to carry out a nitrogen substitution. Then, ultraviolet light having an optical power of 1.4 mW/cm² at 365 nm was irradiated with a mercury lamp under the same nitrogen current of 14 mL/minute for 15 minutes.

The composition of the exposed portion was analyzed. The reaction product of methyl methacrylate was approximately 11 wt % and the unreacted methyl methacrylate was approximately 12 wt %.

### (4). Development (Removal of Unreacted Monomer)

The mask made of a quartz glass on the above-obtained film was separated. The film-attached soda glass was immersed in methanol at room temperature for 3 hours. Then, the film was separated from the soda glass. The film was heated under atmospheric pressure at 80° C. for 10 hours to evaporate and remove the methanol.

The exposed portion of the thus-obtained film was measured for a polymethyl methacrylate content with a NMR. The polymethyl methacrylate content was approximately 11 wt % based on the weight of the film.

### (5). Production of Optical Waveguide Parts and Evaluation Thereof

Y-branch optical waveguides were cut out from the film so as not to give any damages. One of the Y-branch optical waveguides was fixed between two soda glass plates with an epoxy thermosetting mixed adhesive having a refractive index n_{D} of 1.556 which was lower than the core portion refractive index n_{D} of 1.59. Both the ends of the incident-light side and the outgoing-light side were polished to expose the ends of the optical waveguide, whereby a Y-branch optical waveguide having a length of 2 cm was produced.

Optical fibers of N.A.=0.21 were connected to the incident light side and the outgoing light side of the obtained optical waveguide respectively. The optical waveguide was measured for a guided wave loss with a light source (AQ 2150, supplied by ANDO) having a wavelength λ of 850 nm. As a result, the best guided wave loss of the optical waveguide was −3.72 dB and the branching ratio was 0.07 dB.

### Examples 2 to 19

Monomers and polycarbonate resins shown in Table 1 were used in place of the monomer and the polycarbonate resin used in the step (1) for the preparation of a solventless resin/photopolymerizable monomer solution in Example 1.

Steps (2) to (5) were carried out in the same manner as in Example 1.

Table 1 shows the results thereof together with the results of Example 1.

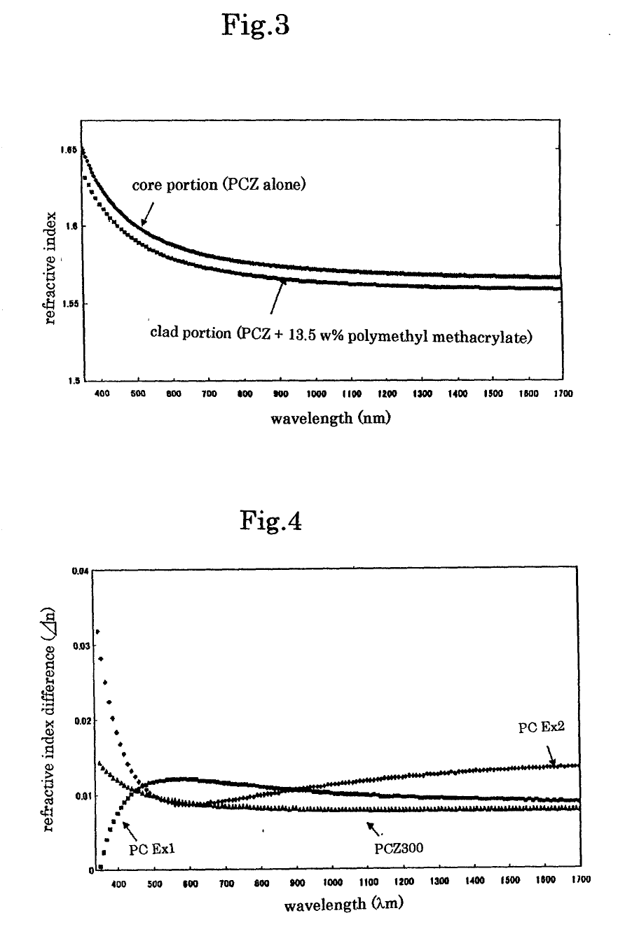

FIG. 2 shows the wavelength dependence of refractive index of each polycarbonate resin alone used in the present invention. FIG. 3 shows the refractive indexes of PCZ and a PCZ containing 13.5% of PMMA. FIG. 4 shows the refractive index differences obtained when the kind of a resin and the content of PMMA were changed.

TABLE 1

| | Resin solution | | | | |
|---|---|---|---|---|---|
| | | | Molecular | Optical waveguide | |
| | monomer | Resin | weight | polymer | Loss (dB) |
| Ex. 1 | MMA | PCZ | 20,000 | 11% | 3.72 |
| Ex. 2 | MMA | PCZ | 30,000 | 12% | 3.73 |
| Ex. 3 | MMA | PCZ | 40,000 | 11% | 3.64 |
| Ex. 4 | MMA | PCZ | 80,000 | 5% | 5.63 |
| Ex. 5 | MMA | PC Ex1 | | 11% | 4.55 |
| Ex. 6 | MMA | PC Ex2 | | 8% | 15.11 |
| Ex. 7 | MA | PCZ | 20,000 | 9% | 6.60 |
| Ex. 8 | MA | PCZ | 30,000 | 4% | 5.67 |
| Ex. 9 | MA | PCZ | 40,000 | 5% | 5.66 |
| Ex. 10 | MA | PC Ex1 | | 8% | 5.50 |
| Ex. 11 | MA | PC Ex2 | | 2% | 6.16 |
| Ex. 12 | MeOEA | PCZ | 20,000 | 4% | 7.31 |
| Ex. 13 | MeOEA | PCZ | 30,000 | 4% | 7.78 |
| Ex. 14 | MeOEA | PCZ | 40,000 | 4% | 7.61 |
| Ex. 15 | MeOEA | PC Ex1 | | 4% | 6.63 |
| Ex. 16 | EA | PCZ | 30,000 | 18% | 8.56 |
| Ex. 17 | EA | PC Ex1 | | 10% | 5.17 |
| Ex. 18 | EMA | PC Ex1 | | 15% | 6.06 |
| Ex. 19 | AlMA | PC Ex1 | | 13% | 8.81 |
| Ex. 20 | ViMA | PC Ex1 | | 3% | 5.36 |

Note:
MMA: methyl methacrylate, MA: methyl acrylate, MeOEA: 2-methoxyethyl acrylate, EA: ethyl acrylate, EMA: ethyl methacrylate, AlMA: allyl methacrylate, ViMA: vinyl methacrylate, PC Ex1: a random copolymer of PCZ chain/PC-S1 chain = 90/10 (wt/wt), PC Ex2: a random copolymer of PCF chain/PC-S2 chain = 50/50 (wt/wt)

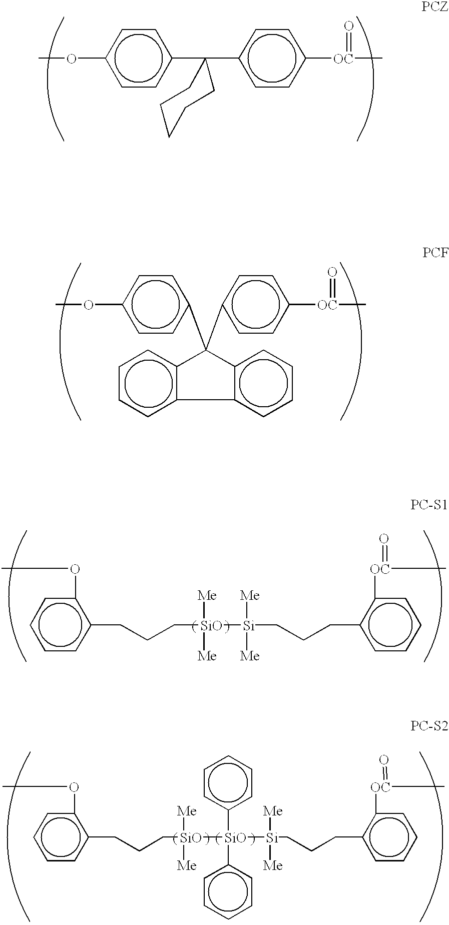

The above chemical formulae represent a constitutional unit (PCZ) induced from 1,1-bis(4-hydroxyphenyl)cyclohexane, a constitutional unit (PCF) induced from 9,9-bis(3-methyl-4-hydroxyphenyl)fluorene, a constitutional unit (PC-S1) having a dimethylsilyl ether chain (20 dimethylsilyl ether groups on average in Examples) in the central part, which is induced from a bisphenol compound, and a constitutional unit (PC-S2) having a dimethylsilyl ether chain and a diphenylsilyl ether chain (36 dimethylsilyl ether groups on average and 4 diphenylsilyl ether groups on average in Examples) in the central part, which is induced from a bisphenol compound.

Effect of the Invention

The present invention uses a highly viscous resin solution containing a photopolymerizable monomer and a thermoplastic resin and containing substantially no organic solvent. Owing to the use of the highly viscous resin solution, the production time of a film is shortened in comparison with a method using a solvent. Further, it is confirmed that the evenness of concentration distribution of the photopolymerizable monomer in the film and reproducibility between lots are excellent over those of the method using a solvent.

What is claimed is:

1. A process for the production of a film having a refractive index distribution, comprising producing a film by using an organic solvent solution containing as essential components a thermoplastic resin, a photopolymerizable monomer and a photopolymerization initiator, exposing the film to light and developing the film,
wherein a highly viscous solution containing as essential components a thermoplastic resin, a photopolymerizable monomer and a photopolymerization initiator and containing substantially no organic solvent is used in place of the organic solvent solution used for the production of the film.

2. A process according to claim 1, wherein the exposure of the film to light is carried out with a mask for an optical waveguide.

3. A process according to claim 1, wherein the thermoplastic resin is a homopolycarbonate or copolycarbonate resin having, as an essential constitutional unit, a constitutional unit induced from 1,1-bis(4-hydroxyphenyl)cyclohexane or a constitutional unit induced from a compound having from 21 to 37 dimethylsilyl ether units on average and having hydroxyphenyl groups at both the terminals of the dimethylsilyl ether units.

4. A process according to claim 1, wherein the photopolymerizable monomer is an ester of an acrylic acid or a methacrylic acid.

5. A process according to claim 1, wherein the photopolymerizable monomer is methyl methacrylate.
